(19) United States
(12) Patent Application Publication
(10) Pub. No.: US 2025/0346780 A1
(43) Pub. Date: Nov. 13, 2025

(54) POLYMER BACKSIDE FILM LAYER FOR MITIGATING SUBSTRATE WARPAGE

(71) Applicant: Avient Corporation, Avon Lake, OH (US)

(72) Inventors: Vinod PURAYATH, Westlake, OH (US); Indraneel SIRCAR, Pune (IN); Ayan DEY, Pune (IN); Krishnamoorthy SIVAKUMAR, Atlanta, GA (US); Kenta OHAMA, Tokyo (JP); Ravi SRIRAMAN, Pune (IN); Gayatri GOLLAPUDI, Pune (IN)

(73) Assignee: Avient Corporation, Avon Lake, OH (US)

(21) Appl. No.: 18/869,447

(22) PCT Filed: Jun. 2, 2023
(86) PCT No.: PCT/US2023/067828

§ 371 Date: Nov. 26, 2024

Related U.S. Application Data
(60) Provisional application No. 63/348,824, filed on Jun. 3, 2022.

(51) Int. Cl. C09D 181/06; C09D 179/08; C09J 5/00; H01L 21/302; H01L 23/00

(52) U.S. Cl. CPC C09D 181/06; C09D 179/085; C09J 5/00; H01L 21/302; H01L 23/562

(57) ABSTRACT

Articles include a substrate, such as a semiconductor wafer, having a backside and a backside film layer deposited on the backside of the substrate, wherein the backside film layer includes a polymer. The backside film layer mitigates bowing or warpage of the substrate which may occur when one or more frontside film layers are deposited on the frontside of the substrate. To form the backside film layer, a film composition including the polymer, optionally wetting agent, and optionally solvent may be deposited on the backside of the substrate.

### CLAIM OF PRIORITY

This application claims priority from U.S. Provisional Patent Application Ser. No. 63/348,824 filed on Jun. 3, 2022, which is hereby incorporated by reference in its entirety.

### TECHNICAL FIELD

The present disclosure relates to polymer film layers deposited on the backside of substrates such as semiconductor wafers. More particularly, a polymer backside film layer may be deposited on the backside of a substrate as means for mitigating bowing or warpage which can occur when one or more frontside film layers are deposited on the frontside of the substrate during processes such as semiconductor device fabrication operations.

### BACKGROUND

Semiconductor device fabrication involves deposition and etching operations, typically on a frontside of a wafer. As the deposited layers build up, they can introduce stress into the wafer, causing the wafer to bow or warp. Although it may be possible with conventional backside deposition techniques to deposit materials having a desired film stress on a backside of the wafer to counteract wafer bowing or warpage, conventional backside deposition techniques may require specialized deposition equipment, which can increase costs and/or introduce complexities.

Accordingly, a need exists for new and more cost-effective solutions for providing backside support to substrates such as semiconductor wafers as means for mitigating bowing or warpage during processes such as semiconductor device fabrication operations.

### SUMMARY

Embodiments of the present disclosure are directed to articles and methods involving a backside film layer that comprises a polymer and is deposited on the backside of a substrate.

According to some embodiments, an article is provided. The article comprises a substrate having a backside and a backside film layer deposited on the backside of the substrate, wherein the backside film layer comprises a polymer.

According to other embodiments, a method for processing a substrate is provided. The method comprises the step of depositing a film composition on a backside of the substrate to form a backside film layer. The film composition comprises polymer, optionally wetting agent, and optionally solvent.

Additional features and advantages of these and other embodiments will be set forth in the detailed description which follows, and in part will be readily apparent to those skilled in the art from the detailed description or recognized by practicing the embodiments described herein, including the detailed description and the claims which follow.

### DRAWINGS

FIG. 1 is a schematic view of an exemplary article, according to one or more embodiments shown and described herein; and

FIG. 2 is a flow diagram of an exemplary method for processing a substrate, according to one or more embodiments shown and described herein.

### DETAILED DESCRIPTION

Reference is made hereinafter in detail to various embodiments of articles and methods, including articles and methods involving a backside film layer that comprises a polymer and is deposited on the backside of a substrate.

The disclosure should not be construed as limited to the embodiments set forth herein. Rather, these embodiments are provided so that this disclosure will be thorough and complete, and will fully convey the subject matter to those skilled in the art.

### DEFINITIONS

Unless otherwise expressly defined, all technical and scientific terms used herein have the same meaning as commonly understood by a person of ordinary skill in the art. The terminology used in the disclosure herein is for describing particular embodiments only and is not intended to be limiting.

Unless otherwise expressly stated, it is not intended that any method disclosed herein be construed as requiring that its steps be performed in a specific order, nor that any apparatus article set forth herein be construed as requiring specific orders or orientations to its individual components.

Unless otherwise expressly stated, it is intended that any composition or mixture disclosed herein may comprise, consist essentially of, or consist of the disclosed components.

As used herein, the singular form of a term is intended to include the plural form of the term, unless the context clearly indicates otherwise.

As used herein, numerical values are not strictly limited to the exact numerical value recited. Instead, unless otherwise expressly stated, each numerical value is intended to mean both the exact numerical value and “about” the numerical value which encompasses (i.e., a functionally equivalent range surrounding that numerical value), such that either possibility is contemplated as an embodiment disclosed herein.

As used herein, the terms “backside” and “frontside” refer to different and opposite sides of the substrate. The frontside is a first side of the substrate. For example, when the substrate is a semiconductor wafer, the frontside typically experiences most of the deposition and etching operations during semiconductor fabrication and is where the semiconductor devices are fabricated. The backside is a second and opposite (i.e., opposite from the frontside) side of the substrate. For example, when the substrate is a semiconductor wafer, the backside typically experiences minimal or no deposition and etching operations during semiconductor fabrication.

As used herein, the terms “bow” or “bowing” refer to a deviation of the center point of the median surface of a free, unclamped wafer from a reference plane established by as determined in accordance with ASTM F534-97.

As used herein, the term “desired film stress” refers a film stress of the backside film layer that results in a bow of less than about 100 μm of the substrate on which the backside film layer is deposited.

As used herein, the term “film composition” refers to the substance (e.g., polymer) or a mixture of two or more substances (e.g., polymer and at least one of solvent and wetting agent, etc.) that is used to form or develop the backside film layer on the backside of the substrate. The film composition may be in the form of a solution such as a liquid solution.

As used herein, the term “film stress” refers to the stress in a film layer as determined in accordance with ASTM E1426-14 and ASTM E915-16.

As used herein, the term “glass transition temperature” refers to the temperature (Tg) at which an amorphous material (or an amorphous region of a semi-crystalline material) undergoes a glass-liquid transition as determined in accordance with ASTM D3418.

As used herein, the terms “substrate” and “wafer” are interchangeable. One of ordinary skill in the art would understand the embodiments described herein may be used prior to or during any other processing operations of a semiconductor wafer during any of the many stages of semiconductor device and/or integrated circuit fabrication.

As used herein, the term “tensile modulus” or “Young's modulus” refers the mechanical property (E) of a material that characterizes its stiffness and is quantified as the ratio of its tensile stress (σ) to its tensile strain (ε) when undergoing elastic deformation, as measured in accordance with ASTM D882-18.

As used herein, the terms “warp” or “warpage” refer to the differences between the maximum and minimum distances of the median surface of a free, unclamped wafer from a reference plane as measured in accordance with ASTM F1390.

### Usefulness

As discussed hereinabove, semiconductor fabrication operations involve formation of various structures, many of which may be two-dimensional. As semiconductor device dimensions shrink and devices are scaled to be smaller, the density of features across a semiconductor substrate increases, resulting in layers of material etched and deposited in various ways, including in three dimensions. For example, 3D-NAND is one technology that is becoming increasingly popular due to lower cost and increased memory density compared to other techniques, such as 2D-NAND, and high reliability in various applications.

In 3D-NAND memory device fabrication, multiple stacked films with thick and high stress depositions are applied and may cause significant wafer warpage, leading to in-plane-distortion (IPD) and defocus problems in the argon fluoride (ArF) photolithography process. Currently, the only solution is backside deposition by a plasma-enhanced chemical vapor deposition (PECVD) method. However, this technique disadvantageously requires specialized deposition equipment, resulting in a larger cost burden for integrated circuit (IC) fabrication plants.

The articles and methods as disclosed herein mitigate the aforementioned problems.

The articles as disclosed herein comprise a substrate having a backside and a backside film layer deposited on the backside of the substrate, wherein the backside film layer comprises a polymer. To form the backside film layer, a film composition comprising the polymer, optionally wetting agent, and optionally solvent may be deposited on the backside of the substrate.

The methods for processing a substrate as disclosed herein comprise the step of depositing a film composition on a backside of the substrate to form a backside film layer. The film composition comprises polymer, optionally wetting agent, and optionally solvent.

The film compositions as disclosed herein may be deposited without the need for specialized deposition techniques or equipment while achieving a desired film stress in the resulting backside film layer to mitigate warpage of the substrate during processes such as semiconductor device and/or integrated circuit fabrication operations.

### Article

The articles disclosed herein comprise a substrate having a backside and a backside film layer deposited on the backside of the substrate, wherein the backside film layer comprises a polymer. To form the backside film layer, a film composition comprising the polymer, optionally wetting agent, and optionally solvent may be deposited on the backside of the substrate.

In embodiments, the article may be a partially or fully fabricated semiconductor device such as a partially or fully fabricated integrated circuit.

### Substrate

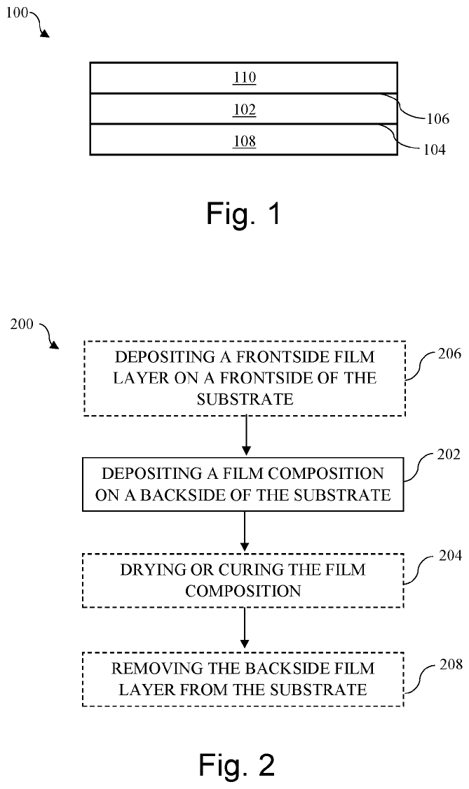

Referring now to FIG. 1, the articles 100 disclosed herein comprise a substrate 102 having a backside 104 and a frontside 106 opposite the backside 104.

In embodiments, the substrate 102 may comprise a semiconductor material. In embodiments, the semiconductor material may be selected from any known semiconductor material. In embodiments, the semiconductor material may be selected from at least one of silicon (Si), silicon carbide (SiC), gallium arsenide (GaAs), gallium nitride (GaN), and germanium (Ge).

In embodiments, the substrate may be substantially circular in shape and have a diameter of 200 mm, 300 mm, or 450 mm.

### Backside Film Layer

A backside film layer 108 is deposited on the backside 104 of the substrate 102 to counteract stresses and resultant bowing or warpage caused by layers deposited on the frontside 106 of the substrate 102.

To form the backside film layer 108, a film composition may be deposited on the backside of the substrate. As described elsewhere herein, the film composition may comprise, consist essentially of, or consist of polymer, optionally wetting agent, and optionally solvent. In some embodiments, the solvent in the film composition may be removed during processing (e.g., with drying) to facilitate forming the backside film layer 108. Accordingly, the backside film layer 108 may comprise polymer, optionally wetting agent, and optionally solvent. In embodiments, after a drying process, no solvent may be present in in the backside film layer 108 or no more than an acceptable minimum residual solvent amount may be present in the backside film layer 108. For example, in embodiments, an acceptable minimum residual solvent amount may be less than or equal to about 0.6 wt %, based on total weight of the backside film layer (i.e., the film composition after drying).

The optimal thickness of the backside film layer 108 may depend on the particular formulation of the film composition used to form the backside film layer 108 and/or the amount of stress induced by the deposition on the frontside 106 of the substrate 102. The backside film layer 108 may be deposited to a thickness at which the wafer bow becomes negligible (e.g., less than about 100 μm of bow). The total thickness of the backside film layer 108 may be achieved by depositing a single layer (e.g., up to 20 μm) or by depositing multiple laminated layers (e.g., up to 50 μm) to form the backside film layer 108.

For example, in embodiments, the backside film layer 108 may have a thickness less than or equal to 50 μm, 30 μm, 20 μm, 10 μm, 8 μm, 5 μm, 3 μm, or 1 μm; and greater than or equal to 0.5 μm or 0.7 μm. Thus, in embodiments, the backside film layer 108 may have a thickness from 0.5 μm to 50 μm, from 0.5 μm to 30 μm, from 0.5 μm to 20 μm, from 0.5 μm to 10 μm, from 0.5 μm to 8 μm, from 0.5 μm to 5 μm, from 0.5 μm to 2 μm, from 0.5 μm to 1 μm, from 0.7 μm to 50 μm, from 0.7 μm to 30 μm, from 0.7 μm to 20 μm, from 0.7 μm to 10 μm, from 0.7 μm to 8 μm, from 0.7 μm to 5 μm, from 0.7 μm to 3 μm, from 0.7 μm to 1 μm, or any and all sub-ranges formed from any of these endpoints.

As described herein, the backside film layer 108 should have a tensile modulus to counteract bowing or warpage caused by depositing layers on the frontside 106 of the substrate 102. For example, in embodiments, the backside film layer 108 may have a tensile modulus greater than 1 GPa, 2 GPa, or 3 GPa. In embodiments, the backside film layer 108 may have a tensile modulus from about 1 GPa to about 2.5 GPa, or from about 1 GPa to about 2.4 GPa, or from about 1 to about 2.3 GPa.

In embodiments, the backside film layer 108 may comprise a blend of polyamide-imide (PAI) and polyimide (PI) at a weight ratio from about 19:1 to about 4:1 (e.g., about 15:1) and having a glass transition temperature from about 230° C. to about 295° C. (e.g., about 291° C.).

### Film Composition

To form the backside film layer, a film composition may be deposited on the backside of the substrate.

In embodiments, a film composition may comprise polymer, optionally wetting agent, and optionally solvent. In embodiments, a film composition may comprise polymer and at least one of wetting agent and solvent. In embodiments, a film composition may comprise polymer, solvent, and optionally wetting agent, and may be used in the form of a solution such as a liquid solution.

In embodiments, the film composition may have a viscosity from about 100 cP to about 27000 cP when measured at 25° C. However, viscosity may be adjusted so as not to exceed a maximum viscosity that can be handled by conventional spin coater equipment, which, in embodiments, may be about 8000 cP when measured at 25° C. Accordingly, in embodiments, the film composition may have a viscosity from about 100 cP to about 8000 cP when measured at 25° C. With viscosity in this range, it is possible to achieve good coating of the film composition onto the backside of the substrate using conventional spin coater equipment.

### Polymer

The backside film layer 108 comprises a polymer that allows for deposition of the film composition to form the backside film layer 108 without the need for specialized deposition equipment while achieving a desired film stress. For example, the film composition including the polymer may be deposited using conventional spin coater equipment and baking apparatus in the photolithography process. The polymer also allows for relatively easy removal of the backside film layer 108 after further processing using conventional spin coater equipment and sufficient solvent.

In some embodiments, the polymer may comprise a single type of polymer. In other embodiments, the polymer may comprise a blend or two or more different types of polymer.

In embodiments, the polymer may be selected from at least one of polybenzimidazole (PBI), polyether imide (PEI), polyamide-imide (PAI), polyimide (PI), polysulfone (PSU), polyphenylsulfone (PPSU), polyethersulfone (PES), and polybenzoxazaole (PBO). For example, in some embodiments, especially suitable polymers include at least one of polyamide-imide (PAI), polyimide (PI), polyphenylsulfone (PPSU), and polyethersulfone (PES).

In embodiments, the polymer may comprise a blend of polyimide (PI) and polybenzimidazole (PBI); or a blend of polysulfone (PSU) and polybenzoxazole (PBO); or a blend of polysulfone (PSU) and polyimide (PI); or a blend of polyamide-imide (PAI) and polyimide (PI); or a blend of polyimide (PI) and at least one of polyamide-imide (PAI), polyimide (PI), and polyether imide (PEI); or a blend of polysulfone (PSU) and at least one of polyimide (PI), polyether imide (PEI), and polyamide-imide (PAI); or a blend of polyimide (PI), polyamide-imide (PAI), and polyether imide (PEI); or a blend of polyamide-imide (PAI), polyimide (PI), and polyethersulfone (PES). For example, in some embodiments, especially suitable polymers include a binary blend of polyamide-imide (PAI) and polyimide (PI); and a ternary blend of polyamide-imide (PAI) and polyimide (PI) and polyethersulfone (PES).

In embodiments in which the polymer includes two or more different polymers, the polymers may be used in blends at suitable weight ratios.

In embodiments in which the polymer comprises a binary blend of a first polymer and a second polymer, the weight ratio of the first polymer to the second polymer may be, for example, 95:5, 85:15, 80:20, 60:40, 50:50, and 40:60.

For example, in some embodiments in which the polymer comprises a binary blend of polyamide-imide (PAI) and polyimide (PI), the weight ratio of PAI to PI may be from 499:1 to 1:4, such as 499:1, 249:1, 166:1, 124:1, 99:1, 19:1, 15:1, 17:3, 4:1, 3:2, 1:1, 2:3, or 1:4.

In embodiments in which the polymer comprises a ternary blend of a first polymer, a second polymer, and a third polymer, the weight ratio of the first polymer to the second polymer to the third polymer may be, for example, 60:15:25, 40:10:50, and 20:5:75.

For example, in some embodiments in which the polymer comprises a ternary blend of polyamide-imide (PAI), polyimide (PI), and polyethersulfone (PES), the weight ratio of PAI to PI to PES may be 12:3:5, 4:1:5, or 4:1:15.

In embodiments in which solvent is included in a film composition, the amount of polymer in the film composition, based on a total weight of the film composition, may be greater than or equal to 1 wt %, 2 wt %, 5 wt %, or 10 wt %; and less than or equal to 50 wt %, 45 wt %, or 40 wt %. Thus, in embodiments, the amount of polymer in the film composition, based on a total weight of the film composition, may be from 1 wt % to 50 wt %, 2 wt % to 50 wt %, from 5 wt % to 45 wt %, from 10 wt % to 40 wt %, or any and all subranges formed from any of these endpoints.

In embodiments in which no solvent is included in a film composition, the amount of polymer in the film composition, based on a total weight of the film composition, may be from 99 wt % to 100 wt %, from 99.5 wt % to 100 wt %, from 99.8 wt % to 100 wt %, or any and all subranges formed from any of these endpoints.

In embodiments, the polymer may have a glass transition temperature greater than or equal to 200° C., 240° C., or 260° C.; and less than or equal to 300° C. or 280° C. Thus, in embodiments, the polymer may have a glass transition temperature from 200°° C. to 300° C., from 200° C. to 280° C., from 240° C. to 300° C., from 240° C. to 280° C., from 260° C. to 300° C., from 260° C. to 280° C., or any and all subranges formed from any of these endpoints.

Suitable commercial embodiments of polyamide-imide are available under the TORLON brand from Solvay, such as grades 4275 and Al-10; polyimide are available under the MATRAMID brand from Huntsman Corporation, such as grade 5318, under the DURATRON brand from Mitsubishi Chemical Advanced materials, such as grade D7000, and under the NOVACLEAR brand from NeXolve Corporation; polyphenylsulfone are available under the RADEL brand from Solvay, such as grades R-5000 and R-5900; and polyethersulfone are available under VERADEL brand from Solvay, such as grade A-201 NT, and under the ULTRASON brand from BASF, such as grade E.

For example, especially suitable commercial embodiments of the polymer include MATRAMID 5318 polyimide from Huntsman, TORLON Al-10 polyamide-imide from Solvay, and ULTRASON E polyethersulfone from BASF.

### Solvent

In embodiments, a film composition may further comprise a solvent for dissolving the polymer. Accordingly, in embodiments, the film composition may be used in the form of a solution such as a liquid solution when deposited on the backside of the substrate to form the backside film layer 108.

In embodiments, solvent may be selected from the group consisting of at least one of amide, imide, imidazole, dioxane, dialkylaminooxopentanoate, valeroacetone, oxopentanoate, dialkylacetamide, and N-alkyl pyrrolidone. In embodiments, the dialkylacetamide may comprise dimethylacetamide (DMAC). In embodiments, the N-alkyl pyrrolidone may comprise N-methyl pyrrolidone (NMP). In embodiments, the dialkylaminooxopentanoate (DAOP) may comprise 5-(dialkylamino)-2-methyl-5-oxopentanoate). Suitable commercial embodiments of the dialkylaminooxopentanoate (DAOP) are available under the RHODIASOLV brand from Solvay, such as POLARCLEAN.

Especially suitable embodiments of the solvent include N-alkyl pyrrolidones such as NMP. Advantageously, when NMP is used as the solvent, it contributes to achieving a desirable viscosity of the film composition, which in turn contributes to achieving good coating of the film composition onto the backside of the substrate using conventional spin coater equipment. As described elsewhere herein, in embodiments, the film composition may have a viscosity from about 100 cP to about 27000 cP, or from about 100 cP to about 8000 cP, when measured at 25° C.

In contrast, for example, when DMAC is used as the solvent, it may contribute to a viscosity of the film composition that is lower than desirable. Further, for example, when DAOP such as POLARCLEAN is used as the solvent, it may contribute to a viscosity of the film composition that is higher than desirable.

In embodiments, the amount of solvent in the film composition, based on a total amount of the film composition, may be greater than or equal to 50 wt %, 55 wt %, or 60 wt %; and less than or equal to 99 wt %, 95 wt %, or 90 wt %. Thus, in embodiments, the amount of solvent in the film composition, based on a total amount of the film composition, may be from 50 wt % to 99 wt %, from 55 wt % to 95 wt %, from 60 wt % to 90 wt %, or any and all subranges formed from any of these endpoints.

In embodiments, the solvent in the film composition may be removed during processing (e.g., with drying) to form the backside film layer 108. Any solvent remaining in the backside film layer after drying may be referred to as residual solvent.

For example, in embodiments, a drying process may be performed including the following steps: (i) soft baking to achieve slow evaporation of the solvent and facilitate film formation (e.g., for about 5 minutes at about 180° C.); (ii) hard baking at or above the boiling point of the solvent to remove residual solvent from the film (e.g., for about 15 minutes at about 200° C.); and (iii) curing to achieve a minimum residual solvent amount and target cure level (e.g., for about 15 minutes at about 250° C.).

In embodiments, an acceptable minimum residual solvent amount may be less than or equal to about 0.6 wt %, based on total weight of the backside film layer (i.e., the film composition after drying).

### Wetting Agent

In embodiments, a film composition may further comprise a wetting agent for improving the wettability of the film composition for depositing (e.g., coating as a liquid solution) on the backside of the substrate.

In embodiments, the amount of wetting agent in the film composition, based on a total amount of the film composition, may be greater than or equal to 0.1 wt %, 0.15 wt %, or 0.18 wt %; and less than or equal to 1 wt %, 0.5 wt %, or 0.25 wt %. Accordingly, in embodiments, the amount of solvent in the film composition, based on a total amount of the film composition, may be from 0.01 wt % to 1 wt %, from 0.15 wt % to 0.5 wt %, from 0.18 wt % to 0.25 wt %, or any and all subranges formed from any of these endpoints. For example, in embodiments, the amount of wetting agent may be 0.2 wt %, based on a total amount of the film composition.

Suitable wetting agents may include conventional or commercially available wetting agents, which may include dyes having wetting properties such as anthraquinone dyestuffs.

For example, especially suitable commercial embodiments of the wetting agent include MACROLEX Green 5B available from Lanxess.

### Non-Limiting Exemplary Embodiments

In embodiments, the film composition may comprise, based on a total weight of the film composition, from 0.5 wt % to 27 wt % of polymer selected from polybenzimidazole and from 73 wt % to 95 wt % of solvent selected from at least one of dialkyl acetamide, N-methyl pyrollidone, and dialkyl formaldehyde.

In embodiments, the film composition may comprise, based on a total weight of the film composition from 2 wt % to 50 wt % of polymer comprising a blend of polyimide and other polymer selected from at least one of polyamide-imide, polyimide, and polyether imide, in a weight ratio of 1:1 to 1:10.

In embodiments, the film composition may comprise, based on a total weight of the film composition, from 2 wt % to 12 wt % of polymer comprising a blend of polysulfone and other polymer selected from at least one of polyimide, polyether imide, and polyamide-imide, in a weight ratio from 1:3 to 3:1, and from 50 wt % to 95 wt % of solvent selected from at least one of dialkylaminooxopentanoate, valeroacetone, oxopentanoate, dialkylacetamide, N-alkyl pyrrolidone.

In embodiments, the film composition may comprise, based on a total weight of the film composition, from 2 wt % to 30 wt % of polymer comprising a blend of polysulfone (or a like polymer) and polyimide (or a like polymer) in a weight ratio from 3:1 to 1:3 and from 70 wt % to 98 wt % of solvent selected from at least one of dialkylaminooxopentanoate, valeroacetone, oxopentanoate, dialkylacetamide, and N-alkyl pyrrolidone.

In embodiments, a film composition may comprise, based on a total weight of the film composition, from 5 wt % to 20 wt % of polymer selected from polysulfone and from 80 wt % to 95 wt % of solvent selected from at least one of dialkylaminooxopentanoate, valeroacetone, dialkylacetamide, and N-methyl pyrrolidone.

In embodiments, the film composition may comprise, based on a total weight of the film composition, from 20 wt % to 99.8 wt % of polymer selected from polyamide-imide and 0.2 to 80 wt % of polyimide. The film may also contain 0.02 wt % to 0.6 wt % of volatile matter. The volatile matter may comprise residual solvent or bound moisture or volatile organic matter produced during curing reaction of the polymer.

In embodiments, the film composition derived from 15 wt/vol % to 50 wt/vol % of polymer solution may comprise, based on a total weight of the film composition, polymer comprising a blend of polyamide-imide and polyimide in a weight ratio from 1:4 to 499:1.

In embodiments, the film composition may comprise, based on a total weight of the film composition, from 2 wt % to 20 wt % of polymer selected from at least one of polyimide, polyamide-imide, and polyether imide.

### Frontside Film Layer

In embodiments, at least one frontside film layer 110 may be deposited on the frontside 106 of the substrate 102. For example, in embodiments, the article 100 may be a partially fabricated integrated circuit.

In embodiments, the at least one frontside film layer 110 may include any number of layers and thicknesses. For example, the at least one frontside film layer 110 may include from 32 to 72 layers and may have a total thickness from about 2 μm to about 4 μm. Further, it should be understood that as advancements in the field may enable an increasing number of layers to be stacked as the frontside film layer 110 on the substrate 102, the requirements for backside mitigation processes using the backside film layer 108 as disclosed herein may also increase. In embodiments, the stress induced in the substrate 102 by the at least one frontside film layer 110 may be from about −500 MPa to about +500 MPa, resulting in a bow that may be between about 200 μm to about 400 μm (for a 300 mm wafer). One skilled in the art would appreciate that the number of layers of the at least one frontside film layer 110 may depend on the application of the 3D-NAND memory device into which it is incorporated.

In embodiments, the at least one frontside film layer 110 may comprise silicon oxide, silicon nitride, polysilicon, tungsten, titanium nitride, or combinations thereof. In embodiments, the at least one frontside film layer 110 may comprise alternating layers of oxide and nitride (e.g., silicon oxide/silicon nitride/silicon oxide/silicon nitride, etc.). In other embodiments, the at least one frontside film layer 110 may comprise alternating layers of oxide and tungsten (e.g., silicon oxide/tungsten/silicon oxide/tungsten, etc.). The at least one frontside film layer 110 may be deposited through chemical vapor deposition techniques such as plasma enhanced chemical vapor deposition (PECVD), low pressure chemical vapor deposition (LPCVD), metal organic chemical vapor deposition (MOCVD), atomic layer deposition (ALD), plasma enhanced atomic layer deposition (PEALD), or through direct metal deposition (DMD).

### Method for Processing

Referring now to FIG. 2, a method for processing a substrate is shown at 200. With reference back to FIG. 1, the method includes step 202 depositing a film composition on a backside 104 of a substrate 102 to form a backside film layer 108. The film composition may be a film composition according to any embodiment described herein.

In embodiments, the depositing of step 202 comprises spin-coating, such as the spin-coating techniques described in U.S. Pat. Nos. 5,238,878; 5,780,105; and 6,436,851, which are incorporated herein by reference in their entireties. For example, conventional equipment such as spin-on coating equipment used in conventional processing such as a photolithography process may be used.

The method 200 of FIG. 2 optionally includes step 204 drying or curing the film composition. In embodiments, the drying or curing step may comprise heating the film composition at a temperature greater than or equal to 90° C., or 120° C., or 150° C., or 180° C.; and less than or equal to 250° C., or 200° C., or 170° C., or 140° C.; and for a time period greater than or equal to 30 seconds, or 1 minute, or 2 minutes; and less than or equal to 35 minutes, or 20 minutes, or 10 minutes, or 5 minutes, or 180 seconds. For example, in embodiments, a drying or curing process may be performed including the following steps: (i) soft baking to achieve slow evaporation of the solvent and facilitate film formation (e.g., for about 5 minutes at about 180° C.); (ii) hard baking at or above the boiling point of the solvent to remove residual solvent from the film (e.g., for about 15 minutes at about 200° C.); and (iii) curing to achieve a minimum residual solvent amount and target cure level (e g, for about 15 minutes at about 250° C.). In embodiments, the drying or curing step may provide the backside film layer 108 with adequate insolubility to prevent removal of the film layer by a solvent during post processing.

With reference back to FIG. 1, the method 200 of FIG. 2 optionally further includes step 206 depositing a frontside film layer 110 on the frontside 106 of the substrate 102. The frontside film layer and the deposition thereof may be in accordance with any embodiment described herein. In embodiments, the step 206 depositing a front film layer 110 on a frontside 106 of the substrate 102 may occur prior to the step 202 depositing a film composition on a backside 104 of the substrate 102.

The method 200 of FIG. 2 optionally further includes step 208 removing the backside film layer 108 from the substrate 102. For example, in embodiments, the backside film layer 108 may be removed by conventional processes such as wet chemical etching. Suitable cleaning agents for removing the backside film layer 108 from the substrate 102 include N-alkyl pyrrolidone such as N-methyl pyrrolidone (NMP).

Every document cited herein is incorporated herein by reference in its entirety unless otherwise specified. The citation of any document is not to be construed as an admission that it is prior art with respect to any invention disclosed or claimed herein. To the extent that any meaning or definition of a term in this document conflicts with any meaning or definition of the same term in a document incorporated by reference, the meaning or definition assigned to that term in this document shall govern.

It will be apparent that modifications and variations are possible without departing from the scope of the disclosure defined in the appended claims. Although some aspects of the present disclosure are identified herein as preferred or particularly advantageous, it is contemplated that the present disclosure is not necessarily limited to these aspects.

What is claimed is:

1. An article comprising:
a substrate having a backside; and
a backside film layer deposited on the backside of the substrate, wherein the backside film layer comprises a polymer.

2. The article of claim 1, wherein the substrate has a frontside and further comprises at least one frontside film layer deposited on the frontside of the substrate.

3. The article of claim 1, wherein the substrate is a semiconductor wafer comprising at least one of silicon, silicon carbide, gallium arsenide, gallium nitride, and germanium, and wherein the article is a partially or fully fabricated integrated circuit.

4. The article of claim 1, wherein the polymer comprises at least one of polybenzimidazole (PBI), polyether imide (PEI), polyamide-imide (PAI), polyimide (PI), polysulfone (PSU), polyphenylsulfone (PPSU), polyethersulfone (PES), and polybenzoxazole (PBO).

5. The article of claim 1, wherein the polymer comprises at least one of polyamide-imide (PAI), polyimide (PI), polyphenylsulfone (PPSU), and polyethersulfone (PES).

6. The article claim 1, wherein the polymer comprises either (i) polyethersulfone (PES); or (ii) a blend of polyamide-imide (PAI) and polyimide (PI); or (iii) a blend of polyamide-imide (PAI) and polyimide (PI) and polyethersulfone (PES).

7. The article of claim 1, wherein the backside film layer is deposited as a film composition comprising the polymer, optionally wetting agent, and optionally solvent comprising at least one of amide, imide, imidazole, dioxane, dialkylaminooxopentanoate, valeroacetone, oxopentanoate, dialkylacetamide, and N-alkyl pyrrolidone.

8. The article of claim 1, wherein the backside film layer is deposited as a film composition comprising the polymer, optionally wetting agent, and solvent, wherein the solvent comprises N-alkyl pyrrolidone, and the film composition has a viscosity from about 100 cP to about 8000 cP when measured at 25° C.

9. The article claim 1, wherein the backside film layer has a thickness from about 0.5 μm to about 50 μm.

10. The article of claim 1, wherein the backside film layer has a tensile modulus from about 1 GPa to about 2.3 GPa.

11. The article of claim 1, wherein the backside film layer comprises a blend of polyamide-imide (PAI) and polyimide (PI) at a weight ratio from about 19:1 to about 4:1 and having a glass transition temperature from about 230° C. to about 295° C.

12. A method for processing a substrate, the method comprising:
depositing a film composition on a backside of the substrate, and, optionally drying and/or curing the film composition, to form a backside film layer, wherein the film composition comprises polymer, optionally wetting agent, and optionally solvent.

13. The method of claim 12, wherein the substrate has a frontside and further comprises at least one frontside film layer deposited on the frontside of the substrate.

14. The method of claim 12, wherein the substrate is a semiconductor wafer comprising at least one of silicon, silicon carbide, gallium arsenide, gallium nitride, and germanium, and wherein the substrate is processed to provide a partially or fully fabricated integrated circuit.

15. The method of claim 12, wherein the polymer comprises at least one of polybenzimidazole (PBI), polyether imide (PEI), polyamide-imide (PAI), polyimide (PI), polysulfone (PSU), polyphenylsulfone (PPSU), polyethersulfone (PES), and polybenzoxazole (PBO).

16. The method of claim 12, wherein the polymer comprises at least one of polyamide-imide (PAI), polyimide (PI), polyphenylsulfone (PPSU), and polyethersulfone (PES).

17. The method of claim 12, wherein the polymer comprises either (i) polyethersulfone (PES); or (ii) a blend of polyamide-imide (PAI) and polyimide (PI); or (iii) a blend of polyamide-imide (PAI) and polyimide (PI) and polyethersulfone (PES).

18. The method of claim 12, wherein the solvent comprises at least one of amide, imide, imidazole, dioxane, dialkylaminooxopentanoate, valeroacetone, oxopentanoate, dialkylacetamide, and N-alkyl pyrrolidone.

19. The method of claim 12, wherein the solvent comprises N-alkyl pyrrolidone and the film composition has a viscosity from about 100 cP to about 8000 cP when measured at 25° C.

20. The method of claim 12, wherein the backside film layer has a thickness from about 0.5 μm to about 50 μm.

21. The method of claim 12, wherein the backside film layer has a tensile modulus from about 1 GPa to about 2.3 GPa.

22. The method of claim 12, wherein the depositing comprises spin-coating.

23. The method of claim 12, wherein the method further comprises drying and/or curing the film composition to form the backside film layer.

24. The method of claim 23, wherein the backside film layer comprises less than or equal to about 0.6 wt % of residual solvent, based on a total weight of the backside film layer.

25. The method of claim 12, wherein the method further comprises removing the backside film layer from the backside of the substrate, and wherein the removing comprises using a cleaning agent comprising N-methyl pyrrolidone (NMP).
